(19) United States
(12) Patent Application Publication
(10) Pub. No.: US 2009/0001608 A1
(43) Pub. Date: Jan. 1, 2009

(54) Semiconductor device and wire bonding method

(75) Inventors: Tatsunari Mii, Tachikawa-shi (JP); Hayato Kiuchi, Tachikawa-shi (JP)

Correspondence Address: Quinn Emanuel Urquhart Oliver & Hedges, LLP;Koda/Androlia, 10th Floor, 865 S. Figueroa Street, Los Angeles, CA, 90017, US

(73) Assignee: Kabushiki Kaisha Shinkawa

(21) Appl. No.: 12/215,317

(22) Filed: Jun. 26, 2008

(30) Foreign Application Priority Data
Jun. 27, 2007 (JP) 2007-168401

(51) Int. Cl. H01L 23/49; B23K 31/00

(52) U.S. Cl. 257/780; 228/180.5; 257/E23.024

(57) ABSTRACT

After bonding a wire to a pad on a surface of a semiconductor chip, a capillary is moved toward a lead and toward a direction opposite to the lead as the wire is fed out, and a first kink that is convex in a direction opposite to the lead, a second kink that is convex toward the lead, and a straight portion that continues from the second kink are formed in the wire. Then, the capillary is moved to form a loop and bonds the wire to the lead. During this bonding, the straight portion is formed into a linear portion in a direction along the surface of the lead, and the linear portion is pressed to the surface of the lead.

### BACKGROUND OF THE INVENTION

1. Field of the Invention

The present invention relates to structures of a semiconductor device and bonding methods of a wire in the semiconductor device.

2. Description of Related Art

An assembling process of a semiconductor device, such as an IC (integrated circuits), includes a wire bonding step for connecting a chip and a lead frame of a semiconductor with a wire. In a commonly employed method for such a wire bonding step, a semiconductor chip and a lead frame are connected with a wire using a capillary through which the wire is inserted, such that an electric discharge from a flame-off electrode forms a ball at a tip end of the wire protruding from the capillary which is then moved to above a pad of the semiconductor chip to perform a primary bonding, and subsequently moved to above a lead of the lead frame to perform a secondary bonding (For example, see Japanese Patent Application Examined Publication Disclosure No. H03-63814).

In the wire bonding method as described above, an area of bonding where the wire and the lead are bonded at the secondary bonding corresponds to an area of the wire between the face portion of the capillary and the lead, and such an area is smaller than an area of bonding where the wire and the pad are bonded in the primary bonding. Consequently, the bonding strength at this portion (second bonding portion) is weak, reducing the bonding reliability.

In view of the above problem, the above-described Japanese Patent Application Examined Publication Disclosure No. H03-63814 proposes a method for improving the strength at a bonding portion in the secondary bonding to increase the bonding reliability, and in this method a wire is folded back after the secondary bonding is done to a lead so that the wire is again bonded to the lead. Further, Japanese Patent Application Unexamined Publication Disclosure No. S52-67262 discloses a method for improving the strength at a bonding portion in the secondary bonding, in which a capillary is moved while connecting a wire to a lead to form a bonding portion in a strip shape, thereby increasing the area of bonding.

In the meantime, in a method that is widely used for manufacturing semiconductor devices, after a semiconductor chip is joined to a lead with a wire, the entirety is sealed with a resin, thus forming a semiconductor package. However, this method has such a problem that, when the temperature of the semiconductor package that has been sealed with a resin increases in a mounting step of the semiconductor package, a stress can be applied to the wire due to a thermal expansion of the resin. In such a case, because the bonding portion between the wire and the lead in the secondary bonding is thin, the stress due to the thermal expansion can be focused on the bonding portion and causes cracks. In order to overcome such a problem, Japanese Patent Application Unexamined Publication Disclosure No. H02-30153 proposes a method for reducing the occurrence of cracks due to thermal expansion of resins. More specifically, in the method of this publication, a bond portion that is thicker than the bonding portion for connecting a wire is provided adjacent to the bonding portion closer to the semiconductor chip in the secondary bonding. Furthermore, Japanese Patent Application Unexamined Publication Disclosure No. H08-293512 discloses a method in which a wire is closely bonded to a lead by moving the capillary from an end portion of the lead in parallel to the lead face when the secondary bonding is executed so that the resin cannot intrude between the lead and the wire.

In the manufacture of semiconductor devices in recent years, a collective sealing method in which a plurality of semiconductor chips are collectively sealed with a resin has been more popularly used than individual sealing method in which each semiconductor chip is individually sealed with a resin. When the collective sealing method is used, such a lead frame is used that a plurality of islands to which semiconductor chips are mounted and a plurality of leads that correspond to respective islands are thickly arranged in a single block, and a leak protection tape is applied to a back side of the lead frame. When such a lead frame is fixed to a bonding stage for bonding, the lead frame is vacuum suctioned to the bonding stage with the tape on the back side interposed therebetween and the lead frame is pressed from above around the block where the plurality of semiconductor chips are closely arranged. Consequently, the lead frame is not very securely fixed to the bonding stage, and thus a wire can disadvantageously cause vibration during wire bonding.

In particular, a problem has been noted that ultrasonic vibration to one wire when bonding this wire causes a crack in a bonding portion between another wire and a lead that have been bonded or in a ball neck on the pad side, resulting in disconnection of the bonded wire.

However, none of Japanese Patent Application Examined Publication Disclosure No. 3-63814 and Japanese Patent Application Unexamined Publication Disclosure Nos. 52-67262, 2-30153 and 8-293512 describe the problem that the ultrasonic vibration during bonding can damage other wires that were bonded previously. In addition, none of the conventional techniques described in the above-described Japanese Patent Application Examined and Unexamined Publication Disclosures solve such a problem.

### SUMMARY OF THE INVENTION

An object of the present invention is to provide a semiconductor device and a method for manufacturing a semiconductor device, in which the ultrasonic vibration during bonding on one wire is prevented from causing damage to another wire that has been bonded previously.

A semiconductor device according to the present invention is manufactured by connecting with a wire between a pad on a surface of a semiconductor chip and a lead and by applying a tape to a surface of a lead frame opposite to a surface for mounting the semiconductor chip, and in the present invention, the semiconductor device comprises

a ball bonding portion at which an initial ball, which is formed at a tip end of a wire protruding from a lower end of a capillary through which the wire is inserted, is bonded to the pad, and

a connecting wire extending from the ball bonding portion to the lead and bonded to the lead; wherein

the connecting wire is formed such that a first kink that is convex in a direction opposite to the lead and a second kink that is convex toward the lead are provided in a wire during a wire feeding step after the ball bonding, and then the wire is looped and bonded to the lead, so that connecting wire has

a first bend that is formed by a portion of the wire extending from the pad toward the lead and then bent in a thickness direction of the semiconductor chip,

a second bend that is bent in an opposite direction to the first bend,

a linear portion extending from the second bend toward the lead along a lead surface, and

a linear portion end part bonded to the lead, and

the side of the linear portion facing the lead is pressed to the lead surface.

A semiconductor device according to the present invention is manufactured by connecting with a wire between a pad on a surface of a semiconductor chip and a lead and by applying a tape to a surface of a lead frame opposite to a surface for mounting the semiconductor chip, and in the present invention the semiconductor device comprises:

a pressed portion formed by crushing a ball neck formed on a ball bonding portion at which an initial ball, which is formed at a tip end of a wire protruding from a lower end of a capillary through which the wire is inserted, is bonded to the pad and by pressing a side of the wire that is folded back on the crushed ball neck portion; and

a connecting wire extending from the pressed portion to the lead and bonded to the lead; wherein

this connecting wire is formed such that a first kink that is convex in a direction opposite to the lead and a second kink that is convex toward the lead are provided in a wire during wire feeding step after the formation of the pressed portion, and then the wire is looped and bonded to the lead, so that the connecting wire has

a first bend that is formed by a portion of the wire extending from the pressed portion toward the lead and then bent in a thickness direction of the semiconductor chip,

a second bend that is bent in an opposite direction to the first bend,

a linear portion that extends from the second bend toward the lead along a lead surface, and

a linear portion end part bonded to the lead, and

the side of the linear portion facing the lead is pressed to the lead surface.

A method of wire bonding according to the present invention is for a semiconductor device manufactured by connecting with a wire between a pad on a surface of a semiconductor chip and a lead and by applying a tape to a surface of a lead frame opposite to a surface for mounting the semiconductor chip, in which the wire of the semiconductor device includes

a first bend formed by a portion of wire extending toward the lead from a ball bonding portion at which an initial ball, which is formed at a tip end of a wire protruding from a lower end of a capillary through which the wire is inserted, is bonded to the pad and bent in a thickness direction of the semiconductor chip,

a second bend that is bent in an opposite direction to the first bend,

a linear portion extending from the second bend toward the lead along a lead surface, and

a linear portion end part bonded to the lead, and the method is comprised of:

a first bonding step for pressing and bonding an initial ball, which is formed at a tip end of a wire protruding from a lower end of a capillary through which the wire is inserted, to the pad;

a reverse step for moving the capillary upward while feeding the wire, and then moving the capillary in a direction opposite to the lead;

a first kink forming step for moving the capillary upward while feeding the wire that is longer than the wire fed out in the reverse step, and then moving the capillary toward the lead across a bonding center on the pad;

a second kink forming step for moving the capillary upward while feeding the wire, and then moving the capillary in the direction opposite to the lead to a position of the bonding center on the pad; and

a second bonding step for moving the capillary back toward the lead to form a loop, and then pressing the capillary to the lead to bond the wire to the lead.

A method of wire bonding according to the present invention is for a semiconductor device manufactured by connecting with a wire between a pad on a surface of a semiconductor chip and a lead and by applying a tape to a surface of a lead frame opposite to a surface for mounting the semiconductor chip, in which the wire of the semiconductor device includes

a pressed portion formed by crushing a ball neck formed on a ball bonding portion at which an initial ball, which is formed at a tip end of the wire protruding from a lower end of a capillary through which the wire is inserted, is bonded to the pad and by pressing a side of the wire that is folded back on the crushed ball neck portion,

a first bend formed by a portion of the wire extending toward the lead from the pressed portion and bent in a thickness direction of the semiconductor chip,

a second bend that is bent in an opposite direction to the first bend,

a linear portion extending from the second bend toward the lead along a lead surface, and

a linear portion end part bonded to the lead; and

the method is comprised of:

a first bonding step for pressing and bonding an initial ball, which is formed at a tip end of a wire protruding from a lower end of a capillary through which the wire is inserted, to the pad;

a pressed portion forming step for moving the capillary upward as the wire is fed out, then moving the capillary toward the direction opposite to the lead, then moving the capillary down to crush the ball neck with a face portion of the capillary, then again moving the capillary upward as the wire is fed out then toward the lead, and then moving the capillary down to press the side of the wire to the crushed ball neck, thus forming the pressed portion;

a reverse step for moving the capillary upward while feeding the wire, and then moving the capillary in a direction opposite to the lead across a bonding center on the pad;

a first kink forming step for moving the capillary upward while feeding the wire that is longer than the wire fed out in the reverse step, and then moving the capillary toward the lead across a bonding center on the pad;

a second kink forming step for moving the capillary upward while feeding the wire, and then moving the capillary in the direction opposite to the lead to a position of the bonding center on the pad; and

a second bonding step for moving the capillary back toward the lead to form a loop, and then pressing the capillary to the lead to bond the wire to the lead.

The present invention advantageously prevents ultrasonic vibrations during bonding one wire from causing damage to another wire that has been bonded previously.

### BRIEF DESCRIPTION OF THE DRAWINGS

FIG. 1 is a plan view showing a lead frame used in a collective sealing method;

FIG. 2 a cross-sectional view showing the lead frame used in the collective sealing method and fixed to a bonding stage;

FIG. 3 is a plan view showing a state in which wire bonding is performed to the lead frame used in the collective sealing method;

FIG. 4 is a diagram showing a wire that connects between a semiconductor chip and a lead in a semiconductor device according to one embodiment of the present invention;

FIG. 5 is a perspective view showing the wire on the lead in the semiconductor device according to the embodiment of the present invention;

FIGS. 6(a) to 6(e) illustrate a wire bonding step for the semiconductor device according to the embodiment of the present invention;

FIG. 7 is a diagram showing a wire that connects between a semiconductor chip and a lead in a semiconductor device according to another embodiment of the present invention;

FIG. 8 is a perspective view showing a pressed portion on a pad of a semiconductor device according to another embodiment of the present invention;

FIGS. 9(a) to 9(f) illustrate a wire bonding step for forming the pressed portion for a semiconductor device according to another embodiment of the present invention; and

FIGS. 10(a) to 10(e) illustrate a wire bonding step after the formation of the pressed portion for a semiconductor device according to another embodiment of the present invention.

### DETAILED DESCRIPTION OF THE INVENTION

Embodiments of a semiconductor device according to the present invention will be described in detail below with reference to the accompanying drawings.

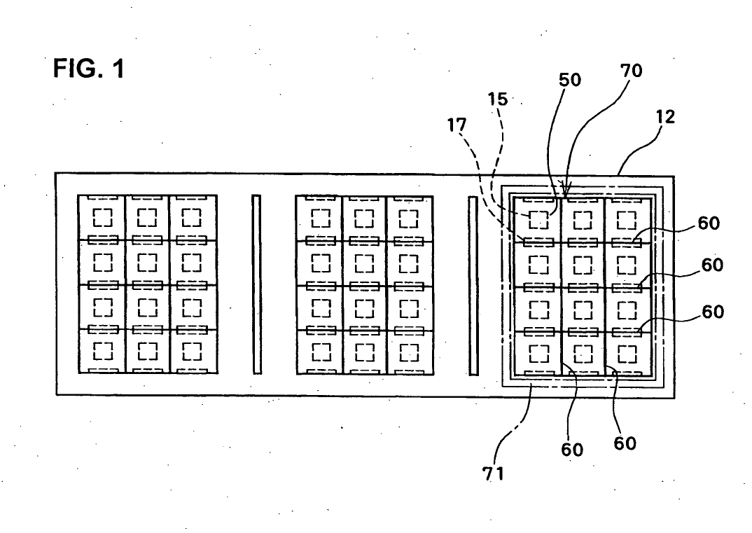

As shown in FIG. 1, a lead frame 12 used in the manufacture of a semiconductor device according to a collective resin sealing method is provided with a plurality of islands 15, to each of which a semiconductor chip is mounted, and a plurality of leads 17 respectively corresponding to the pads on the semiconductor chips that are mounted to the islands 15. Each island 15 and each lead 17 corresponding to the island 15 form a pair that constitutes one of segments 50. Each segment 50 corresponds to a single semiconductor device to be formed after the mounting of the semiconductor chips, wire bonding, and resin sealing followed by dicing the lead frame at dicing regions 60 provided between the segments. The segments 50 are closely provided in the lead frame 12, and a plurality of the segments 50 form one of blocks 70. Each block 70 corresponds to an area that is collectively sealed in the resin sealing. In addition, the blocks 70 are provided so as to be spaced from an adjacent one of the blocks 70 so that it is possible for a pressing frame 71 to press around one block 70 from above to fix the block 70 during wire bonding.

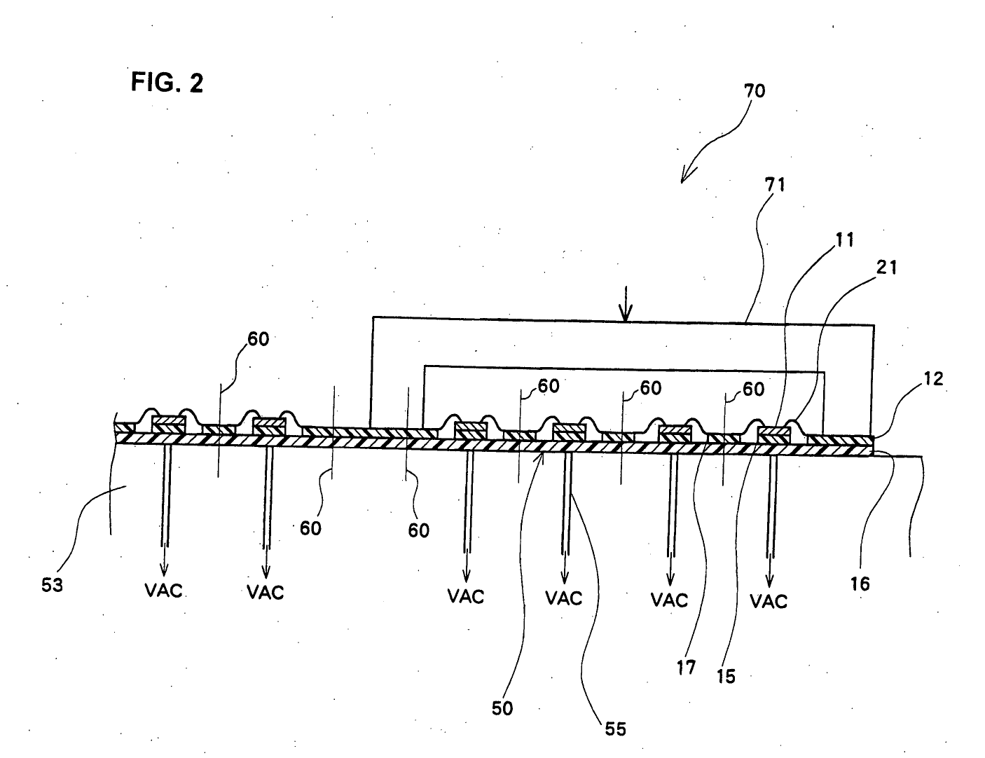

As shown in FIG. 2, a peelable tape 16 for preventing sealing resin from leaking from the islands 15 and the leads 17 is applied to a back side of the lead frame 12. The above-described lead frame 12 is transferred onto a bonding stage 53 after semiconductor chips 11 are mounted to the islands 15. Then, the lead frame 12 is fixed to the bonding stage 53 by vacuum suction to the bonding stage 53 via vacuum suction holes 55 formed in the bonding stage 53 with the tape 16 therebetween, while being pressed by the pressing frames 71 from above around the corresponding blocks 70. After that, each of the semiconductor chips 11 is connected with each of the leads 17 via wires (or connecting wires) 21.

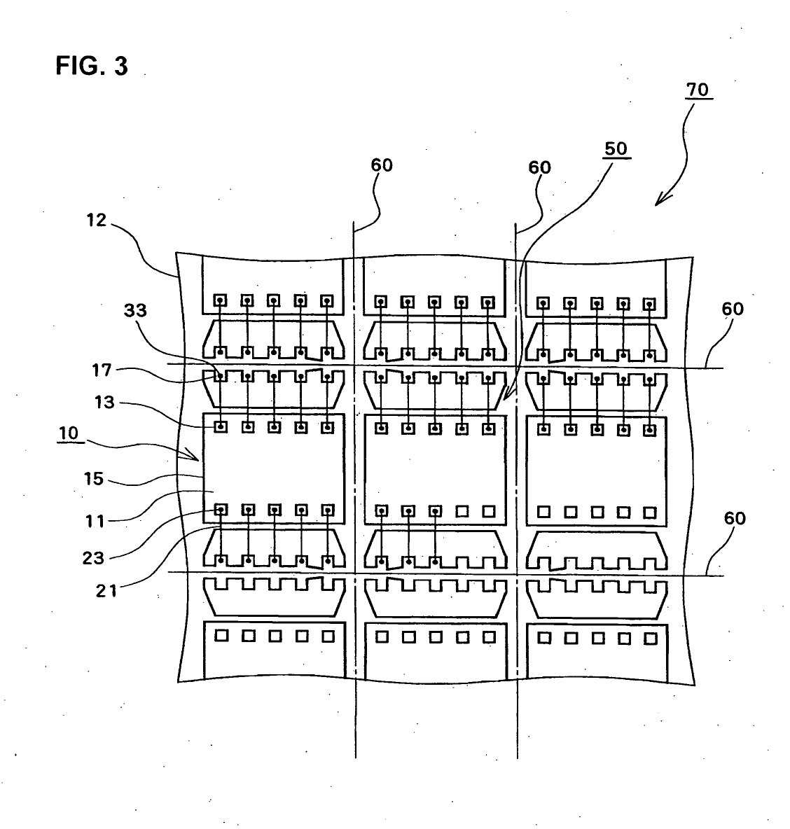

Once the lead frame 12 is fixed on the bonding stage 53 as shown in FIG. 3, pads 13 on the surface of each semiconductor chip 11 attached to the corresponding one of the island 15 are sequentially connected to the leads 17 by wires 21, respectively. Therefore, in the wire bonding step, bonding to the next one of the pads 13 or the leads 17 is performed at a position adjacent to the wire 21 that has been bonded. Then, when the connection between the pads 13 of all of the semiconductor chips 11 that are on the lead frame 12 and the leads 17 that respectively correspond to the pads 13 is completed, the lead frame 12 is collectively sealed with resin by each block 70 in the following step, and then diced at dicing regions 60 to produce semiconductor devices 10.

Such a semiconductor device has no externally coupled electrode protruding from a resin sealed package and has an externally coupled electrode provided on the back side of the package, and thus it is called Quad Flat Non-leaded Package (QFN).

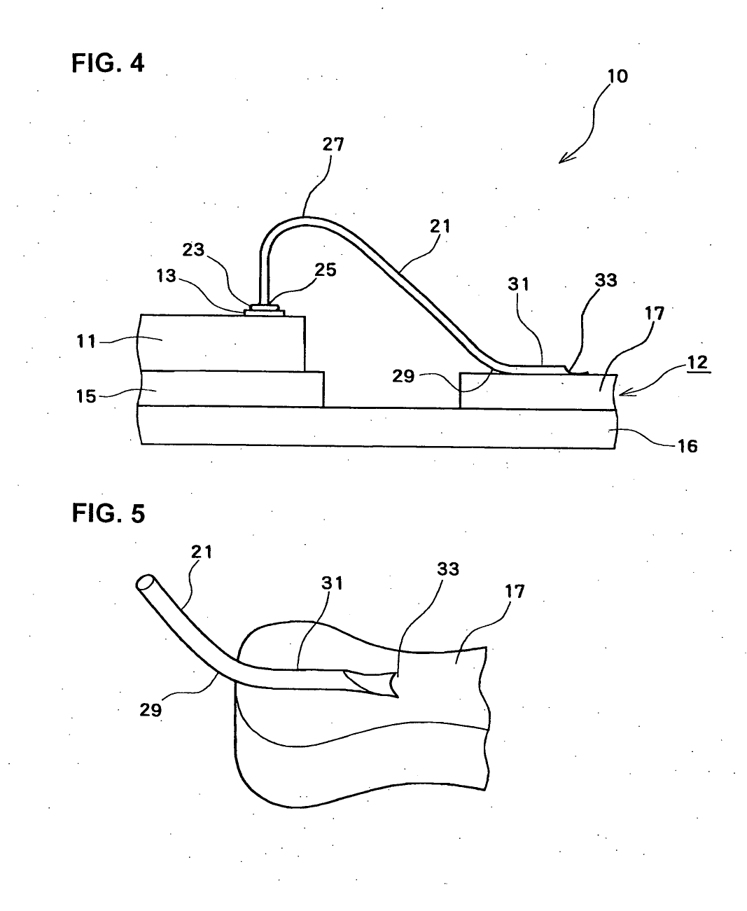

As shown in FIG. 4, in the semiconductor device 10, the pad 13 provided on the surface of a semiconductor chip 11 mounted to the island 15 of the lead frame 12 to which the tape 16 is applied to the back side of the lead frame 12 is connected to the lead 17 of the lead frame 12 via the wire (connecting wire) 21. The wire (connecting wires) 21 is comprised of a pressure-bonded ball 23 bonded to the pad 13 provided on the surface of the semiconductor chip 11, a ball neck portion 25 having a varied cross-section from the pressure-bonded ball 23 toward the wire 21, a first bend 27 that is formed by the wire rising from the ball neck portion 25 in the thickness direction of the semiconductor chip 11, extending toward the lead 17, and then being bent downward in the thickness direction of the semiconductor chip 11, a second bend 29 that is bent upward which is an opposite direction to the first bend 27, a linear portion 31 that extends from the second bend 29 toward the lead 17 in a direction along the surface of the lead 17, a end part 33 of the linear portion that is bonded to the lead 17.

As shown in FIG. 5, the end part 33 of the linear portion of the wire 21 is pressed to the lead 17 by a capillary while being subjected to ultrasonic vibration during the bonding, thereby bonded to the lead 17. The end part 33 of the linear portion is deformed during bonding into a shape according to the shape of the tip end of the capillary, and the shape of the end part 33 is such that the end part 33 gradually becomes thinner from the rod-like linear portion 31 toward the end part 33 of the linear portion.

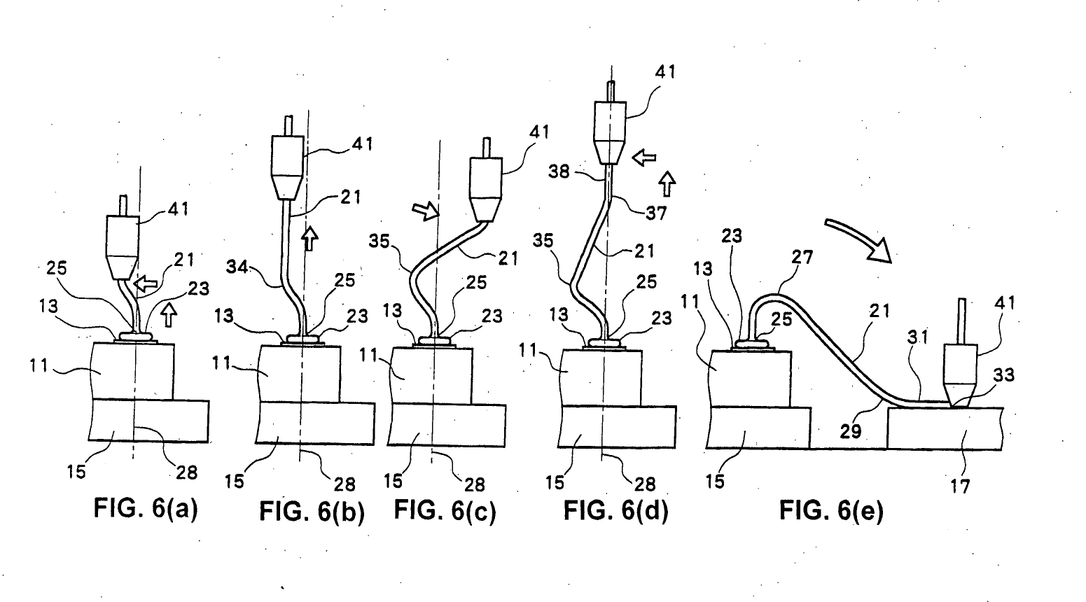

The wire 21 is configured such that both sides (ends) of the wire 21 are fixed at the pressure-bonded ball 23 on the pad side and at the end part 33 of the linear portion on the lead side, and that the lead side of the linear portion 31 is pressed toward the surface of the lead 17. The pressing force is provided by bonding the wire 21 during the bonding step as shown in FIG. 6.

As shown in FIG. 6(a), following the first bonding step in which an initial ball (not shown in the drawing) formed at a tip end of the wire 21 is bonded to the pad 13 by a capillary 41 while being subjected to ultrasonic vibration, and the pressure-bonded ball 23 and the ball neck portion 25 are formed on the pad 13, a reverse step is performed in which the capillary 41 is moved in a direction opposite to the lead 17 after the capillary 41 is moved upward as the wire 21 is fed out from the tip end of the capillary 41. With the reverse step, the capillary 41 is positioned on a side opposite to the lead 17 centering a bonding center line 28 on the pad 13. When the reverse step is completed, the wire 21 is inclined from the pad 13 toward the direction opposite to the lead 17. At the same time, because the wire 21 is maintained by the capillary 41 in a direction substantially vertical to the surface of the pad 13, a bending habit is formed in the wire 21 in the vicinity of the tip end of the capillary 41 when the reverse step is completed so as to be convex in the direction opposite to the lead 17.

Following the reverse step, a first kink forming step is performed. As shown in FIG. 6(b), a bend portion 34 is formed by the capillary 41 when the capillary 41 is moved upward as the wire 21 is fed out from the tip end of the capillary 41, because the bending habit is formed in the wire 21 so as to be convex in the direction opposite to the lead 17 in the previous reverse step. The wire 21 that is fed out by the upward movement of the capillary 41 is longer than the wire fed out in the reverse step. Then, as shown in FIG. 6(c), once the capillary 41 is moved toward a direction of the lead 17 across the bonding center line 28 on the pad 13, the bend portion 34 is further bent, thereby forming a first kink 35 that is convex in the direction opposite to the lead 17. The capillary 41 is positioned on a side of the lead 17 centering a bonding center line 28 on the pad 13, and the first kink 35 is formed on the side opposite to the lead 17 centering a bonding center line 28 on the pad 13. Accordingly, the wire 21 is inclined between the first kink 35 and the capillary 41 from the direction opposite to the lead 17 to the direction of the lead 17. At the same time, because the wire 21 is maintained by the capillary 41 in a direction substantially vertical to the surface of the pad 13, a bending habit is formed in the wire 21 in vicinity of the tip end of the capillary 41 when the first kink forming step is completed so as to be convex in the direction of the lead 17.

Following the first kink forming step, a second kink forming step is performed. As shown in FIG. 6(d), the capillary 41 is moved in the direction opposite to the lead 17 after the capillary 41 is moved upward as the wire 21 is fed out, so that the center of the capillary 41 is positioned at the bonding center line 28 on the pad 13. Because the bending habit is formed in the wire 21 so as to be convex in the direction of the lead 17 in the previous first kink forming step, a second kink 37 is formed that is convex in the direction of the lead 17 by the capillary 41 moving upward and toward the direction opposite to the lead 17. Further, a straight portion 38 where the wire 21 extends linearly is formed between the second kink 37 and the capillary 41.

Following the step of forming the second kink 37, a second bonding step is performed. As shown in FIG. 6(e), after the second kink forming step, the capillary 41 is moved, to form a loop, from the bonding center line 28 on the pad 13 toward the lead 17. By this movement, the first kink 35 is further bent to make the first bend 27 that rises from the ball neck portion 25 in the thickness direction of the semiconductor chip 11, extends toward the lead 17, and then is bent downward in the thickness direction of the semiconductor chip 11. Further, the second kink 37 forms the second bend 29 that is bent upward which is the opposite direction to the first bend 27. Then, the straight portion 38 formed between the second kink 37 and the capillary 41 in the second kink forming step makes the linear portion 31 that extends from the second bend 29 along the surface of the lead 17. The end of the linear portion 31 makes the end part 33 of the straight portion that is bonded to the lead 17.

As described above, in this embodiment, after the wire 21 is bonded to the pad 13 on the surface of the semiconductor chip 11, the capillary 41 is moved in the direction of the lead 17 and then in the direction opposite to the lead 17 as the wire 21 is fed out, and then the first kink 35 convex in the direction opposite to the lead 17, the second kink 37 convex in the direction of the lead 17, and the straight portion 38 continues from the second kink 37 are formed in the wire 21, followed by the bonding of the wire 21 to the lead 17 by moving the capillary 41 to form a loop. Accordingly, it is possible to form the straight portion 38 in the linear portion 31 in a direction along the surface of the lead 17 during the bonding, and to bond the wire 21 while the linear portion 31 is pressed to the surface of the lead 17.

In the wire 21 that is bonded according to the above-described method, the linear portion 31 is supported by the lead 17 in the thickness direction of the semiconductor chip 11. For this reason, even when the ultrasonic vibration is applied during bonding of a different one of the wires 21, the linear portion 31 of the wire 21 that has been bonded can suppress the vibration of the wire 21 in the thickness direction of the semiconductor chip 11 or in the direction vertical to the surface of the lead 17. Consequently, it is advantageously possible to prevent the wire 21 that has been bonded from being damaged by ultrasonic vibrations applied later to a different one of the wires 21.

Moreover, because the linear portion 31 is pressed to the lead 17, even when the wire 21 that has been bonded is vibrated in the direction along the surface of the lead 17 due to the ultrasonic vibration during the bonding of a different one of the wires 21, the vibration energy can be consumed as a frictional force between the linear portion 31 and the lead 17. Accordingly, it is advantageously possible to reduce the vibration in the direction along the surface of the lead 17 and to prevent the wire 21 from being damaged.

As described above, because the linear portion 31 of the wire (connecting wire) 21 is pressed to the lead 17, it is advantageously possible to reduce the vibration in the direction vertical to the surface of the lead 17 and the vibration in the direction along the surface of the lead 17 at the same time.

This embodiment can advantageously prevent the bonding portion of the wire 21 that has been bonded to the lead 17 from being damaged by the ultrasonic vibration applied to a different one of the wires 21 due to the reduced vibration by the support and the frictional force of the linear portion 31, even in such a state that the lead frame 12 is not very securely fixed in which the lead frame 12 is suctioned to the bonding stage 53 with a tape 16 interposed therebetween and pressed from above around each of the blocks 70 as in a case in which the semiconductor device 10 is manufactured by the collective sealing method as described with reference to FIG. 1 through FIG. 3.

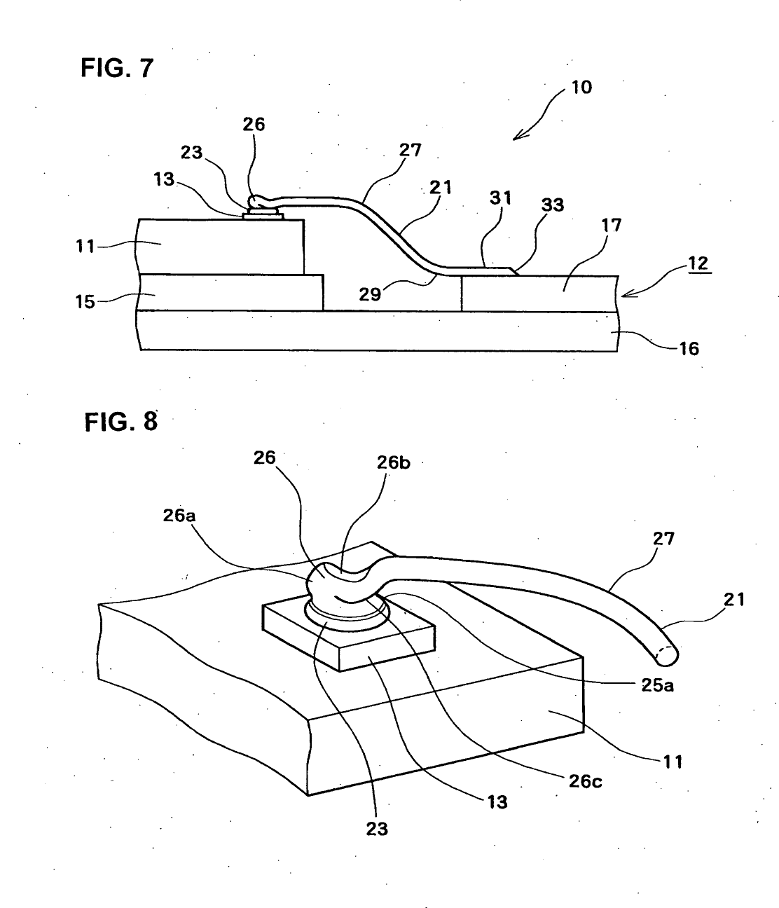

A different embodiment will be now described with reference to FIG. 7 through FIG. 10. The like reference numerals are used for the like components as in the previously described embodiment, and an explanation for such a component is omitted.

As shown in FIG. 7, in the semiconductor device 10 shown therein, the pads 13, which are provided on the surfaces of the semiconductor chips 11 mounted to the islands 15 of the lead frame 12 to which the tape 16 is applied to the back side of the lead frame 12, are connected to the leads 17 of the lead frame 12 via wires (connecting wires) 21. The wire (connecting wire) 21 is comprised of the pressure-bonded ball 23 bonded by bonding to the pad 13 provided on the surface of the semiconductor chip 11, a pressed portion 26 formed by crushing the ball neck portion 25 having a varied cross-section from the pressure-bonded ball 23 toward the wire 21 and by pressing the side of the wire 21 that is folded back on the crushed ball neck portion 25, the first bend 27 that is formed by the wire portion extending from the pressed portion 26 toward the lead 17 and then being bent downward in the thickness direction of the semiconductor chip 11, the second bend 29 that is bent upward which is an opposite direction to the first bend 27, the linear portion 31 that extends from the second bend 29 toward the lead 17 in the direction along the surface of the lead 17, and the end part 33 of the linear portion that is bonded to the lead 17.

As shown in FIG. 8, the pressed portion 26 formed on the pad 13 on the surface of the semiconductor chip 11 includes a crushed portion 25a formed by crushing the ball neck portion 25 onto the pressure-bonded ball 23 on the pad 13 to have a flat upper surface, a folding back portion 26a formed by folding the wire 21 back from the crushed portion 25a so as to be convex in the direction opposite to the lead 17, and a planar portion 26b formed by pressing a side of the wire 21 following the folding back portion 26a toward the crushed portion 25a to have a flat upper surface by the capillary during the pressing. The surface of the planar portion 26b on the side of the pad 13 is pressed to the upper surface of the crushed portion 25a. The linear portion 31 and the end part 33 of the linear portion of the wire 21 have the same configurations as those of the previous embodiment described with reference to FIG. 5.

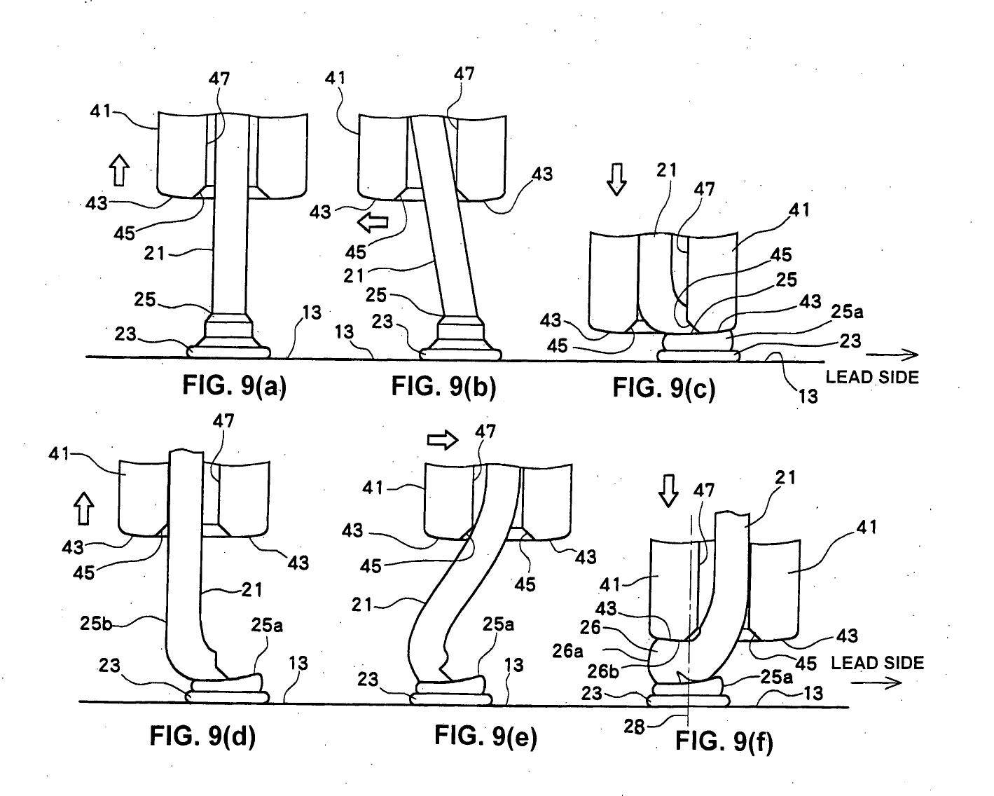

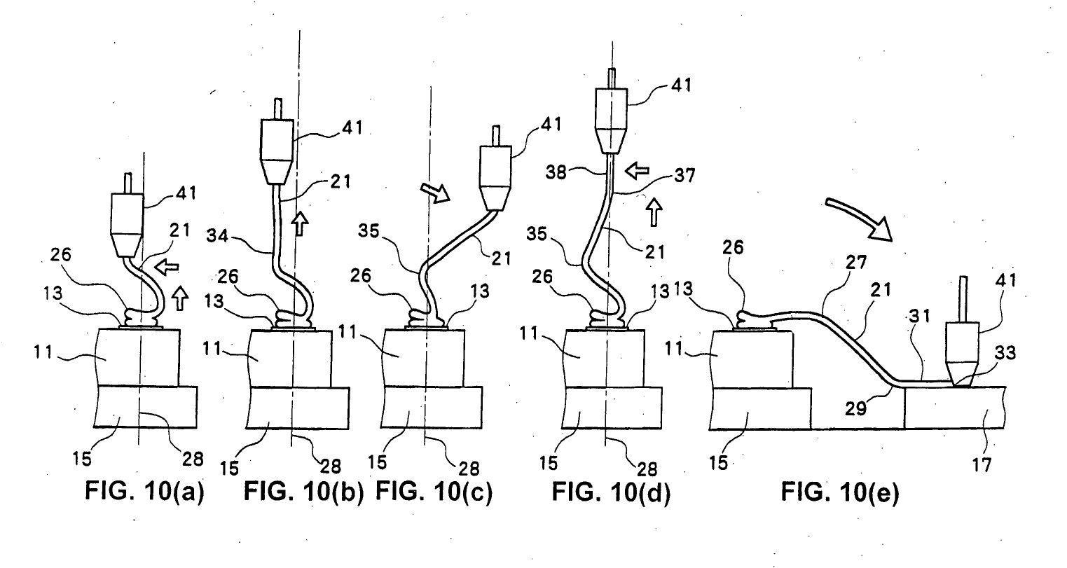

In this wire 21, both sides (ends) of the wire 21 are fixed at the pressure-bonded ball 23 on the pad side and at the end part 33 of the linear portion on the lead 17 side, the pad 13 side of the pressed portion 26 is pressed to the crushed portion 25a, and the lead side of the linear portion 31 is pressed toward the surface of the lead 17. The pressing force for these pressed portions is provided by bonding the wire 21 during the bonding step as shown in FIG. 9 and FIG. 10.

The bonding steps in this embodiment will be described below.

Similarly to the previously described embodiment, a first bonding step is performed so that an initial ball (not shown in the drawing) formed at the tip end of the wire 21 is bonded to the pad 13 by the capillary 41 while being subjected to ultrasonic vibration, and the pressure-bonded ball 23 and the ball neck portion 25 are formed on the pad 13.

After the first bonding step, a pressed portion forming, step as shown in FIG. 9(a) through FIG. 9(f) is performed. Although the lead 17 is omitted in FIG. 9(a) through FIG. 9(f), the right side of the drawing corresponds to the lead 17 side. In the pressed portion forming step, after the capillary 41 is moved upward as the wire 21 is fed out as shown in FIG. 9(a), the capillary 41 is, as shown in FIG. 9(b), moved in the direction opposite to the lead 17 until the face portion 43 of the capillary 41 on the lead 17 side moves to above the ball neck portion 25. At this time, the wire 21 is inclined from the ball neck portion 25 toward the direction opposite to the lead 17. Then, as shown in FIG. 9(c), the capillary 41 is moved down and the ball neck portion 25 is crushed by the face portion 43 of the capillary 41 to form the crushed portion 25a on the pressure-bonded ball 23. As the ball neck portion 25 is thus crushed by the face portion 43 of the capillary 41, the upper surface of the crushed portion 25a has a flat surface following the shape of the face portion 43 of the capillary. In addition, the wire 21 is folded in the direction opposite to the lead 17 at the crushed portion 25a and extends along the inner surface of the straight hole 47 of the capillary 41 opposite to the lead 17 in the direction vertical to the pad 13.

Subsequently, as shown in FIG. 9(d), the capillary 41 is again moved upward as the wire 21 is fed out. Then, the wire 21 is fed out linearly along the straight hole 47 of the capillary 41. After that, as shown in FIG. 9(e), the capillary 41 is moved toward the lead 17. Then, the wire 21 is pressed toward the lead 17 by an inner chamfer portion 45 of the capillary 41, and bent at a bending portion 25b that continues from the crushed portion 25a. Then, the capillary 41 is moved toward the lead 17 until the face portion 43 of the capillary 41 that is on the opposite side to the lead 17 is moved to above the pressure-bonded ball 23. Then, as shown in FIG. 9(f), the capillary 41 is moved downward, and a side of the wire 21 is pressed onto the crushed portion 25a that has been formed by crushing the ball neck portion 25. By this pressing of the wire 21, the bent portion of the wire 21 is folded back toward the crushed portion 25a, thereby forming the folding back portion 26a. Because the pressed portion 26 of the wire 21 on the pad 13 side is pressed to the upper surface of the crushed portion 25a by the pressing, the upper surface of the pressed portion 26 is made flat by the face portion 43 of the capillary 41. Upon completion of the pressed portion forming step, the capillary 41 is positioned on the lead 17 side with reference to the bonding center line 28 of the pad 13.

The pressed portion 26 where the wire 21 is folded back and pressed to the surface of the pad 13 is formed according to the above-described method. The lower surface of this pressed portion 26 is pressed to the crushed portion 25a formed on the pressure-bonded ball 23 of the pad 13 and is accordingly supported in the thickness direction of the semiconductor chip 11 or the direction vertical to the pad 13, and it is also pressed to the crushed portion 25a by the pressing force at the same time.

In the configuration described above, even when the ultrasonic vibration is applied during bonding of a different one of the wires (connecting wires) 21, the pressed portion 26 of the wire 21 that has been bonded can suppress the vibration of the wire 21 in the thickness direction of the semiconductor chip 11 or in the direction vertical to the surface of the pad 13. Consequently, it is advantageously possible to prevent the wire 21 that has been bonded from being damaged by ultrasonic vibrations applied later to a different one of the wires 21.

Moreover, because the pressed portion 26 is pressed to the upper surface of the crushed portion 25a formed on the pad 13, even when the wire 21 that has been bonded is vibrated in the direction along the surface of the pad 13 due to the ultrasonic vibration during the bonding of a different one of the wires 21, the vibration energy can be consumed as a frictional force between the lower surface of the pressed portion 26 and the upper surface of the crushed portion 25a. Accordingly, it is advantageously possible to reduce the vibration in the direction along the surface of the pad 13, and to prevent the wire 21 from being damaged.

As described above, in the connected wire 21, because the pressed portion 26 is pressed to the crushed portion 25a formed on the pad 13, it is advantageously possible to reduce the vibration in a direction vertical to the surface of the pad 13 and the vibration in a direction along the surface of the pad 13 at the same time.

The following description will be made for a step for forming, looping, and bonding the wire 21 to the lead 17, after forming the pressed portion 26 where the wire 21 is folded back on the pad 13 according to the above-described steps.

As shown in FIG. 10(a), following the pressed portion forming step described with reference to FIG. 9, the reverse step is performed in which the capillary 41 that is positioned on the side of the lead 17 centering the bonding center line 28 of the pad 13 upon the completion of the previous pressed portion forming step is moved in the direction opposite to the lead 17 after the capillary 41 is moved upward as the wire 21 is fed out from the tip end of the capillary 41. With the reverse step, the wire 21 that rises from the pad 13 on the side of the lead 17 is curved and inclined toward the direction opposite to the lead 17. At the same time, because the wire 21 in the capillary 41 is maintained in the direction substantially vertical to the surface of the pad 13, the bending habit is formed in the wire 21 in vicinity of the tip end of the capillary 41 when the reverse step is completed so as to be convex in the direction opposite to the lead 17.

Similarly to the previous embodiment, as shown in FIG. 10(b) through FIG. 10(d), the, first kink forming step and the second kink forming step are performed after the reverse step.

Then, following the second kink forming step, as shown in FIG. 10(e), the second bonding step is performed. As shown in FIG. 10(e), after the second kink forming step, the capillary 41 is moved to form a loop, from the bonding center line 28 on the pad 13 toward the lead 17. By this movement, the first kink 35 is made into the first bend 27, the second kink 37 is made into the second bend 29, the straight portion 38 is made into the linear portion 31 that extends from the second bend 29 along the surface of the lead 17, and the end of the linear portion 31 is made into the end part 33 of the linear portion that is bonded to the lead 17.

As described above, in this embodiment, after the wire 21 is bonded onto the pad 13 on the surface of the semiconductor chip 11, the wire 21 is folded back to form the pressed portion 26 that is pressed to the crushed portion 25a of the ball neck portion 25, the capillary 41 is moved in the direction of the lead 17 and then in the direction opposite to the lead 17 as the wire 21 is fed out, and then the first kink 35 convex in the direction opposite to the lead 17, the second kink 37 convex in the direction of the lead 17, and the straight portion 38 continues from the second kink 37 are formed in the wire 21, followed by the bonding of the wire 21 to the lead 17 by moving the capillary 41 form a loop. Accordingly, it is possible to form the straight portion 38 into the linear portion 31 in the direction along the surface of the lead 17 during the bonding and to bond the linear portion 31 to the lead 17 while the end part 33 of the linear portion that is continuous from the linear portion 31 is pressed to the surface of the lead 17. In the wire 21 that is bonded according to the above-described method, the linear portion 31 is supported by the lead 17 in the thickness direction of the semiconductor chip 11.

In this embodiment, the lower surface of the pressed portion 26 is pressed to the crushed portion 25a formed on the pressure-bonded ball 23 of the pad 13 and supported in the thickness direction of the semiconductor chip 11 or the direction vertical to the pad 13, and the bonding strength onto the pad 13 can be improved by the pressing force. Accordingly, it is possible to suppress the vibration of the wire 21 on the pad 13 side. Further, similarly to the previous embodiment, the linear portion 31 of the wire 21 is supported in the thickness direction of the semiconductor chip 11 of the wire 21 or the direction vertical to the surface of the lead 17 and pressed to the lead 17, and the vibration energy can be consumed by the pressing force between the linear portion 31 and the lead 17. Accordingly, it is also possible to suppress the vibration of the wire 21 on the lead 17 side. Thus, it is possible to suppress a greater degree of vibration for the wire 21 as a whole as compared to the previous embodiment, and it is advantageously possible to prevent the bonding portions of the wire 21 bonded to the pad 13 and to the lead 17 from being damaged by the ultrasonic vibration applied to a different one of the wires 21 more effectively.

This embodiment, as in the previously described embodiment, can advantageously prevent more effectively the joined portion of the wire 21 that is bonded to the pad 13 and the joined portion between the wire 21 and the lead 17 from being damaged by the ultrasonic vibration applied to a different one of the wires 21 due to the reduced vibration by the support and the frictional force of the pressed portion 26 and the linear portion 31, even in such a state that the lead frame 12 is not very securely fixed in which the lead frame 12 is suctioned to the bonding stage 53 with the tape 16 interposed therebetween and pressed from above around each of the blocks 70 as in a case that the semiconductor device 10 is manufactured by the collective sealing method as described with reference to FIG. 1 through FIG. 3.

What is claimed is:

1. A semiconductor device manufactured by connecting with a wire between a pad on a surface of a semiconductor chip and a lead and by applying a tape to a surface of a lead frame opposite to a surface for mounting the semiconductor chip, the semiconductor device comprising:
a ball bonding portion at which an initial ball, which is formed at a tip end of a wire protruding from a lower end of a capillary through which the wire is inserted, is bonded to the pad, and
a connecting wire extending from the ball bonding portion to the lead and bonded to the lead;
the connecting wire being formed so that a first kink convex in a direction opposite to the lead and a second kink convex toward the lead are provided in a wire during a wire feeding step after the ball bonding, and then the wire is looped and bonded to the lead, thus having
a first bend formed by a portion of the wire extending from the pad toward the lead and then bent in a thickness direction of the semiconductor chip,
a second bend bent in an opposite direction to the first bend,
a linear portion extending from the second bend toward the lead along a lead surface, and
a linear portion end part bonded to the lead, and
a side of the linear portion facing the lead being pressed to the lead surface.

2. A semiconductor device manufactured by connecting with a wire between a pad on a surface of a semiconductor chip and a lead and by applying a tape to a surface of a lead frame opposite to a surface for mounting the semiconductor chip, the semiconductor device comprising:
a pressed portion formed by crushing a ball neck formed on a ball bonding portion at which an initial ball, which is formed at a tip end of a wire protruding from a lower end of a capillary through which the wire is inserted, is bonded to the pad, and by pressing a side of the wire that is folded back on the crushed ball neck portion, and
a connecting wire extending from the pressed portion to the lead and bonded to the lead
the connecting wire being formed so that a first kink convex in a direction opposite to the lead and a second kink convex toward the lead are provided in a wire during wire feeding step after the formation of the pressed portion, and then the wire is looped and bonded to the lead, thus having
a first bend formed by a portion of the wire extending from the pressed portion toward the lead and then bent in a thickness direction of the semiconductor chip,
a second bend bent in an opposite direction to the first bend,
a linear portion extending from the second bend toward the lead along a lead surface, and
a linear portion end part bonded to the lead, and
a side of the linear portion facing the lead being pressed to the lead surface.

3. A method of wire bonding for a semiconductor device manufactured by connecting with a wire between a pad on a surface of a semiconductor chip and a lead and by applying a tape to a surface of a lead frame opposite to a surface for mounting the semiconductor chip, in which the wire of the semiconductor device is comprised of
a first bend formed by a portion of the wire extending toward the lead from a ball bonding portion at which an initial ball, which is formed at a tip end of a wire protruding from a lower end of a capillary through which the wire is inserted, is bonded to the pad and bent in a thickness direction of the semiconductor chip,
a second bend bent in an opposite direction to the first bend,
a linear portion extending from the second bend toward the lead along a lead surface, and
a linear portion end part bonded to the lead;
the method comprising the steps of:
a first bonding step for pressing and bonding an initial ball, which is formed at a tip end of a wire protruding from a lower end of a capillary through which the wire is inserted, to the pad;
a reverse step for moving the capillary upward while feeding the wire, and then moving the capillary in a direction opposite to the lead;
a first kink forming step for moving the capillary upward while feeding the wire that is longer than the wire fed out in the reverse step, and then moving the capillary toward the lead across a bonding center on the pad;
a second kink forming step for moving the capillary upward while feeding the wire, and then moving the capillary in the direction opposite to the lead to a position of the bonding center on the pad; and
a second bonding step for moving the capillary back toward the lead to form a loop, and then pressing the capillary to the lead to bond the wire to the lead.

4. A method of wire bonding for a semiconductor device manufactured by connecting with a wire between a pad on a surface of a semiconductor chip and a lead and by applying a tape to a surface of a lead frame opposite to a surface for mounting the semiconductor chip, in which the wire of the semiconductor device is comprised of
a pressed portion formed by crushing a ball neck formed on a ball bonding portion at which an initial ball, which is formed at a tip end of the wire protruding from a lower end of a capillary through which the wire is inserted, is bonded to the pad and by pressing a side of the wire that is folded back on the crushed ball neck portion,
a first bend formed by a portion of the wire extending toward the lead from the pressed portion and bent in a thickness direction of the semiconductor chip,
a second bend bent in an opposite direction to the first bend,
a linear portion extending from the second bend toward the lead along a lead surface, and
a linear portion end part bonded to the lead;
the method comprising the steps of:
a first bonding step for pressing and bonding an initial ball, which is formed at a tip end of a wire protruding from a lower end of a capillary through which the wire is inserted, to the pad;
a pressed portion forming step for moving the capillary upward as the wire is fed out, then moving the capillary toward the direction opposite to the lead, then moving the capillary down to crush the ball neck with a face portion of the capillary, then again moving the capillary upward as the wire is fed out then toward the lead, and then moving the capillary down to press the side of the wire to the crushed ball neck, thus forming the pressed portion;
a reverse step for moving the capillary upward while feeding the wire, and then moving the capillary in a direction opposite to the lead across a bonding center on the pad;
a first kink forming step for moving the capillary upward while feeding the wire that is longer than the wire fed out in the reverse step, and then moving the capillary toward the lead across a bonding center on the pad;
a second kink forming step for moving the capillary upward while feeding the wire, and then moving the capillary in the direction opposite to the lead to a position of the bonding center on the pad; and
a second bonding step for moving the capillary back toward the lead to form a loop, and then pressing capillary to the lead to bond the wire to the lead.
